(19) United States
(12) Patent Application Publication
(10) Pub. No.: US 2022/0093673 A1
(43) Pub. Date: Mar. 24, 2022

(54) IMAGE SENSOR PACKAGES

(71) Applicant: Samsung Electronics Co., Ltd., Suwon-si (KR)

(72) Inventors: Raehyung DO, Asan-si (KR); Jongho LEE, Hwaseong-si (KR); Kundae YEOM, Asan-si (KR)

(73) Assignee: Samsung Electronics Co., Ltd., Suwon-si (KR)

(21) Appl. No.: 17/306,267

(22) Filed: May 3, 2021

(30) Foreign Application Priority Data
Sep. 24, 2020 (KR) 10-2020-0124073

(51) Int. Cl. H01L 27/146; H05K 3/40; H05K 1/03; H04N 5/374

(52) U.S. Cl. CPC H01L 27/14643; H05K 3/4007; H05K 2201/09118; H01L 27/14609; H04N 5/374; H05K 1/03

(57) ABSTRACT

An image sensor package includes a circuit board, an image sensor chip on the circuit board, a stack bump structure on the image sensor chip, a bonding wire connecting the circuit board to the stack bump structure, a dam element on the image sensor chip and covering both the stack bump structure and the bonding wire, and a molding element contacting the dam element on the circuit board and covering both the image sensor chip and the bonding wire.

### CROSS-REFERENCE TO RELATED APPLICATION

This application is based on and claims priority under 35 U.S.C. § 119 to Korean Patent Application No. 10-2020-0124073, filed on Sep. 24, 2020, in the Korean Intellectual Property Office, the disclosure of which is incorporated by reference herein in its entirety.

### BACKGROUND

The inventive concepts relates to an image sensor package, and more particularly, to an image sensor package having improved reliability.

The image sensor package may include a bonding wire electrically connecting an image sensor chip to a circuit board. Because of a small diameter, the bonding wire may be easily damaged. Accordingly, there is a demand for improving the reliability of an image sensor package by reducing damage to a bonding wire.

### SUMMARY

The inventive concepts provides an image sensor package having improved reliability by reducing damage to a bonding wire that connects an image sensor chip and a circuit board to each other.

According to some example embodiments of the inventive concepts, an image sensor package may include a circuit board, an image sensor chip on the circuit board, a stack bump structure on the image sensor chip, a bonding wire connecting the circuit board to the stack bump structure, a dam element on the image sensor chip and covering both the stack bump structure and the bonding wire, and a molding element contacting the dam element on the circuit board and covering both the image sensor chip and the bonding wire.

According to some example embodiments of the inventive concepts, an image sensor package may include a circuit board, an image sensor chip on the circuit board, a stack bump structure adjacent to outer surfaces of the image sensor chip and including a first bump and a second bump on the first bump, a bonding wire having a first end that is located between the first bump and the second bump and an opposite second end that is on the circuit board and connects the image sensor chip to the circuit board, a dam element covering both the stack bump structure and the bonding wire, located along a periphery of the image sensor chip, and including at least one inner surface at least partially defining an inner cavity within the dam element, and a molding element located along a periphery of the dam element on the circuit board and sealing both the image sensor chip and the bonding wire.

According to some example embodiments of the inventive concepts, there is provided an image sensor package including a circuit board, an image sensor chip on the circuit board, a stack bump structure adjacent to opposite outer surfaces of the image sensor chip and including a first bump and a second bump on the first bump, a bonding wire having a first end that is located between the first bump and the second bump and an opposite second end that is located on the circuit board and connects the image sensor chip to the circuit board, a dam element covering both the stack bump structure and the bonding wire, located adjacent to the opposite outer surfaces of the image sensor chip, and including at least one inner surface at least partially defining an inner cavity within the dam element and exposing a central portion of the image sensor chip, an optical element on the dam element, and a molding element sealing both the image sensor chip and the bonding wire and located on opposite outer surfaces of the optical element, wherein the molding element includes a material different from a material of the dam element.

### BRIEF DESCRIPTION OF THE DRAWINGS

Example embodiments of the inventive concepts will be more clearly understood from the following detailed description taken in conjunction with the accompanying drawings in which:

FIG. 1 is a plan view of an image sensor package according to some example embodiments;

FIG. 2 is a cross-sectional view of the image sensor package taken along a line II-IT of FIG. 1, according to some example embodiments;

FIGS. 3 and 4 are partial cross-sectional views of the image sensor package of FIG. 2, according to some example embodiments;

FIG. 5 is a plan view for explaining a connection relationship between an image sensor chip and a circuit board of the image sensor package of FIGS. 1 and 2, according to some example embodiments;

FIG. 6 is a cross-sectional view of an image sensor package according to some example embodiments;

FIG. 7 is a cross-sectional view of an image sensor package according to some example embodiments;

FIG. 8 is a plan view of an image sensor package according to some example embodiments;

FIG. 9 is a cross-sectional view of an image sensor package according to some example embodiments;

FIG. 10 is a cross-sectional view of an image sensor package according to some example embodiments;

FIG. 11 is a cross-sectional view of an image sensor package according to some example embodiments;

FIG. 12 is a cross-sectional view of an image sensor package according to some example embodiments;

FIGS. 13, 14, 15, 16, and 17 are main cross-sectional views for explaining a manufacture method of an image sensor package, according to some example embodiments;

FIGS. 18A, 18B, 18C, 18D, and 18E are main cross-sectional views for explaining a wire bonding method of FIGS. 13 and 14 using a bonding device, according to some example embodiments;

FIG. 19 is a structure diagram of a camera using an image sensor package, according to some example embodiments; and

FIG. 20 is a block structure diagram of an imaging system including an image sensor package, according to some example embodiments.

### DETAILED DESCRIPTION

Hereinafter, some example embodiments of the inventive concepts will be described in detail with reference to the attached drawings. Some example embodiments of the present inventive concepts may be implemented by only one example embodiment, and some example embodiments may be implemented by combining one or more example embodiments.

Accordingly, the inventive concepts are not limited to one example embodiment.

An expression used in the singular encompasses the expression of the plural, unless it has a clearly different meaning in the context. Sizes of components in the drawings may be exaggerated for convenience of explanation. It will be understood that the same reference numerals are assigned to the same or similar constituent elements throughout the specification.

In some example embodiments, when a certain part with a layer, film, region, plate, etc. is said to be “on” another part, the part may be “above,” “below,” and/or “horizontally adjacent to” the other part. In some example embodiments, when a certain part with a layer, film, region, plate, etc. is said to be “on” another part, the part may be “indirectly on” or “directly on” the other part. When a certain part is said to be “indirectly on” another part, an interposing structure and/or space may be present between the certain part and the other part such that the certain part and the other part are isolated from direct contact with each other. Conversely, when a certain part is said to be “directly on” another part, it means that there is no other part between the certain part and the other part such that the certain part is in direct contact with the other part.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

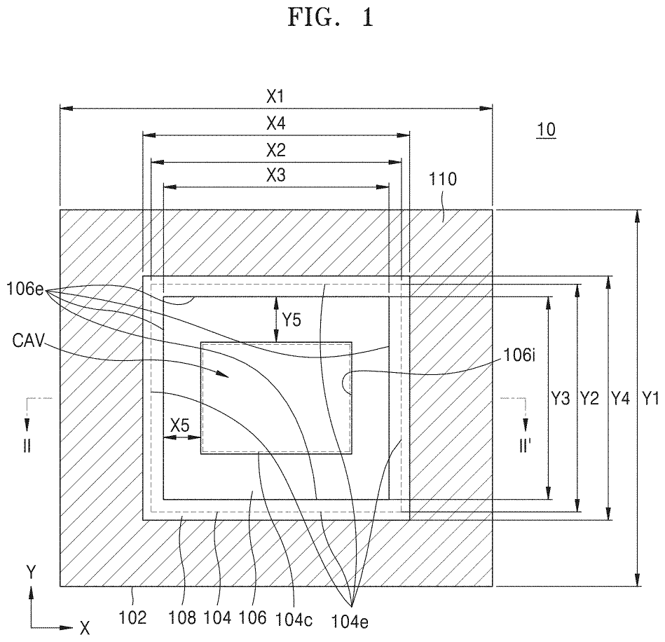

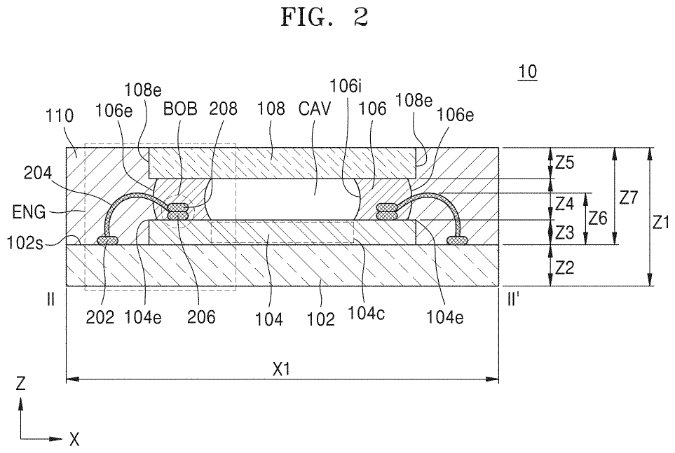

FIG. 1 is a plan view of an image sensor package according to some example embodiments, and FIG. 2 is a cross-sectional view of the image sensor package taken along a line II-IT of FIG. 1 according to some example embodiments.

In detail, for convenience, FIG. 1 does not illustrate a bonding wire connecting an image sensor chip 104 to a circuit board 102. On a plan view, an image sensor package 10 may have lengths X1 and Y1 in X and Y directions, respectively. X1 may be greater than Y1. In some example embodiments, X1 may be between about 8 mm and about 9 mm, and Y1 may be between about 7 mm and about 8 mm. When vertically shown, the image sensor package 10 may have a height (or a thickness) Z1 in a Z direction. In some example embodiments, Z1 may be between about 1.5 mm and about 2.0 mm.

As illustrated in FIGS. 1 and 2, the image sensor package 10 may include the image sensor chip 104 disposed on the circuit board 102. The circuit board 102 may be a Printed Circuit Board (PCB) or a lead frame. When the circuit board 102 is a PCB, internal wires may be arranged in the circuit board 102, and an external connection terminal may be formed on a lower surface of the circuit board 102.

On a plan view, the circuit board 102 may have the lengths X1 and Y1 in the X and Y directions, respectively. The lengths of the circuit board 102 in the X and Y directions, that is, X1 and Y1, may be a size of the image sensor package 10. When vertically viewed, the circuit board 102 may have a height (or a thickness) Z2 in the Z direction. In some example embodiments, Z2 may be between about 0.2 mm and about 0.3 mm.

The image sensor chip 104 may be a CMOS image sensor (CIS) chip, but some example embodiments are not limited thereto. The image sensor chip 104 may be embodied on a wafer, and the wafer may include silicon (Si), gallium arsenide (GaAs), or the like. In the image sensor chip 104, various circuit elements, for example, a transistor, a passive element, and the like, may be formed.

On a plan view, the image sensor chip 104 may have lengths X2 and Y2 in the X and Y directions, respectively. X2 may be greater than Y2. In some example embodiments, X2 may be between about 5 mm and about 6 mm, and Y2 may be between about 4 mm and 5 mm. When vertically viewed, the image sensor chip 104 may have a height (or a thickness) Z3 from the circuit board 102 in the Z direction. Z3 may be greater than Z2. In some example embodiments, Z3 may be between about 0.2 mm and about 0.3 mm.

The image sensor package 10 may include a stack bump structure BOB disposed on the image sensor chip 104. The stack bump structure BOB may be disposed around both edges (e.g., opposite outer edges, for example opposite outer surfaces 104e) of the image sensor chip 104. The stack bump structure BOB may include a first bump 206 disposed on the image sensor chip 104 and a second bump 208 disposed on the first bump 206.

In some example embodiments, the stack bump structure BOB may include two bumps, that is, the first bump 206 and the second bump 208, but the stack bump structure BOB may include three or more bumps. The first bump 206 and the second bump 208 forming the stack bump structure BOB may have ball shapes. In some example embodiments, the first bump 206 and the second bump 208 may each include aluminum, copper, gold, silver, or nickel.

The image sensor package 10 may include a bonding wire 204 connecting the circuit board 102 to the stack bump structure BOB. A ball bump 202 on the circuit board 102 may be electrically and physically connected to the stack bump structure BOB on the image sensor chip 104 by using the bonding wire 204. On a plan view, the bonding wire 204 may have a length of between about 500 μm and about 900 μm in the X direction.

When the circuit board 102 is connected to the image sensor chip 104 by the bonding wire 204, a reverse bonding method may be used as described below. That is, the reverse bonding method may be a method of connecting the bonding wire 204 on the circuit board 102 in a direction towards the image sensor chip 104. When the reverse bonding method is used, a length of the bonding wire 204 may be reduced.

The ball bump 202 may have a ball shape. The ball bump 202 may include the same material as the first bump 206 and the second bump 208. The circuit board 102 and the bonding wire 204 may be connected (or bonded) to each other through ball bonding. The image sensor chip 104 and the bonding wire 204 may be connected (or bonded) to each other through the ball bonding. The bonding wire 204 may include the same material as the first bump 206 and the second bump 208. In some example embodiments, the first bump 206 and the bonding wire 204 may form the same body (e.g., may be separate parts of a single, continuous (e.g., uniform) piece of material).

The image sensor package 10 may include a dam element 106 disposed on the image sensor chip 104. The dam element 106 may cover both the stack bump structure BOB and the bonding wire 204. As shown in at least FIG. 1, the dam element 106 may be disposed (e.g., located) along a periphery (e.g., one or more outer edges, including one or more outer surfaces 104e) of the image sensor chip 104 (e.g., the outer surfaces 106e of the dam element 106 may be adjacent to corresponding outer surfaces 104e of the image sensor chip 104) and have an inner cavity CAV within the dam element 106 on (e.g., at least partially defined by) an inner side (e.g., inner surface 106i) of the dam element 106. Restated, the dam element 106 may include one or more inner surfaces 106i that at least partially define an inner cavity CAV within the dam element. As shown in at least FIGS. 1-2, the dam element 106 may be adjacent to both edges (e.g., opposite outer surfaces 104e) and/or all edges (e.g., all outer surfaces 104e) of the image sensor chip 104, and an optical element 108 may be installed on said dam element 106. The inner cavity CAV may be referred to as an inner through hole.

As described herein, where a first element is described to be adjacent to an edge or surface of another second element, an outer surface of the first element may be adjacent to the corresponding outer surface of the second element in the X direction and/or Y direction. An outer surface of the first element may be understood to be proximate to a corresponding outer surface of the second element in the X direction and/or Y direction when a distance between said respective outer surfaces in the X direction and/or Y direction is equal to or less than a cross-sectional width of the first element and/or of the second element in the in the X direction and/or Y direction. For example, with reference to FIG. 1 the dam element 106 may be adjacent to an outer surface 104e of the image sensor chip 104 when a distance in the X direction and/or Y direction between the outer surface 104e and a corresponding (e.g., closest) outer surface 106e of the dam element 106 is equal to or less than 0.1*Y3, 0.1*Y2, 0.1*X2, and/or 0.1*X3.

The inner cavity CAV may expose a central portion 104c of the image sensor chip 104 that overlaps with the inner cavity CAV in the Z direction (which extends perpendicular to the upper surface 102s of the circuit board 102). The central portion of the image sensor chip 104, which is exposed by the inner cavity CAV, may be an image sensing area. The dam element 106 may support an optical element 108 as described below. The dam element 106 may prevent a molding element 110 from entering the inner cavity CAV of the image sensor chip 104 during the manufacture. The dam element 106 may be an adhesive element that attaches or supports the optical element 108 described below.

On a plan view, the dam element 106 may have lengths X3 and Y3 in X and Y directions, respectively. X3 may be greater than Y3. In some example embodiments, X3 may be between about 4 mm and about 5 mm, and Y3 may be between about 3 mm and about 4 mm. Also, on the plan view, the dam element 106 may have widths X5 and Y5 in the X and Y directions, respectively. The widths X5 and Y5 may be identical to each other. In some example embodiments, X5 and Y5 may each be between about 0.3 mm and about 0.4 mm.

When vertically viewed, the dam element 106 may have a height (or thickness) Z4 from the image sensor chip 104 in the Z direction. Z4 may be less than or greater than Z3. In some example embodiments, Z4 may be between about 0.1 mm and about 0.3 mm.

The dam element 106 may include a material different from a material of the molding element 110 described below. The dam element 106 may include an insulating material. The dam element 106 may include thermosetting resin such as epoxy resin, thermoplastic resin such as polyimide, and resin formed by including a reinforcement material such as an inorganic filler in the thermosetting resin and the thermoplastic resin.

In some example embodiments, a maximum height Z6 of the image sensor package 10 from an upper surface 102s of the circuit board 102 to the bonding wire 204 may be less than a sum of the height Z3 (e.g., thickness in the Z direction) of the image sensor chip 104 and the height Z4 (e.g., thickness in the Z direction) of the dam element 106. As described herein, a “height” may refer to a distance and/or thickness in a direction extending perpendicular to the upper surface 102s of the circuit board 102 (e.g., the Z direction, also referred to herein as a vertical direction that is perpendicular to the upper surface 102s of the circuit board 102, where the X and Y directions are parallel to the upper surface 102s and perpendicular to the Z direction).

The image sensor package 10 may include the optical element 108 disposed on the dam element 106. The optical element 108 may be disposed on the image sensor chip 104. An upper surface (or a surface) of the optical element 108 may be exposed to the outside. In some example embodiments, the optical element 108 may be disposed on the inner cavity CAV of the image sensor chip 104.

The optical element 108 may facilitate light to be incident to the image sensor chip 104. In some example embodiments, the optical element 108 may include at least one material selected from sapphire, glass, reinforced glass, plastic, a polycarbonate (PC)-based material, and a polyamide (PI)-based material. In some example embodiments, the optical element 108 may be a lens of which optical features such as a refractive index, magnetic permeability, and the like are designed within a desired range.

On a plan view, the optical element 108 may have lengths X4 and Y4 in the X and Y directions, respectively. X4 may be greater than Y4. In some example embodiments, X4 may be between about 5 mm and about 6 mm, and Y4 may be between 4 mm and about 5 mm. When vertically viewed, the optical element 108 may have a height (or a thickness) Z5 in the Z direction. Z5 may be greater than Z4. In some example embodiments, Z4 may be between 0.6 mm and about 0.8 mm.

In some example embodiments, a maximum height Z6 of the image sensor package 10 from the upper surface of the circuit board 102 to the bonding wire 204 may be less than a sum of the height Z3 of the image sensor chip 104, the height Z4 of the dam element 106, and the height Z5 of the optical element 108.

The image sensor package 10 may include the molding element 110 disposed on the circuit board 102, contacting the dam element 106, and covering both the image sensor chip 104 and the bonding wire 204. The molding element 110 may seal the image sensor chip 104 and the bonding wire 204. The molding element 110 may cover part of the bonding wire 204. The molding element 110 may be on both sides (e.g., opposite sides, for example opposite outer surfaces 108e) of the optical element 108. An upper surface 110s of the molding element 110 may be on the same plane as (e.g., may be coplanar with) the upper surface 108s of the optical element 108. The molding element 110 may be located along (e.g., contacting) a periphery (e.g., outer surfaces 106e) of the dam element 106 on the circuit board 102 and may seal (e.g., enclose, cover, etc.) both the image sensor chip 104 and the bonding wire 204.

As described above, the molding element 110 may include a material different from that of the dam element 106. The molding element 110 may include an insulating material. The molding element 110 may include thermosetting resin such as epoxy resin, thermoplastic resin such as polyimide, and resin formed by including a reinforcement material such as an inorganic filler in the thermosetting resin and the thermoplastic resin. In some example embodiments, the molding element 110 may be an epoxy molding compound or an adhesive film.

On the plan view, lengths of the molding element 110 may be the same as the lengths of the circuit board 102, that is, the lengths X1 and/or Y1, in the X and Y directions, respectively. In some example embodiments, on the plan view, the lengths of the molding element 110 may be less than the lengths of the circuit board 102, that is, the lengths X1 and/or Y1, in the X and Y directions, respectively. When vertically viewed, the molding element 110 may have a height (or a thickness) Z7 in the Z direction. In some example embodiments, Z7 may be between about 1.0 mm and about 1.3 mm.

The image sensor package 10 described so far may include the stack bump structure BOB disposed on the image sensor chip 104. Accordingly, the stack bump structure BOB of the image sensor package 10 may improve the package reliability because the bonding wire 204, which connects the circuit board 102 and the image sensor chip 104 to each other, may be less likely cut because of stress applied from the dam element 106 and the molding element 110.

Hereinafter, detailed structures of the image sensor chip 104, the stack bump structure BOB, the dam element 106, the bonding wire 204, and the molding element 110 of the image sensor package 10 and a connection relationship between the image sensor chip 104 and the circuit board 102 will be described in detail.

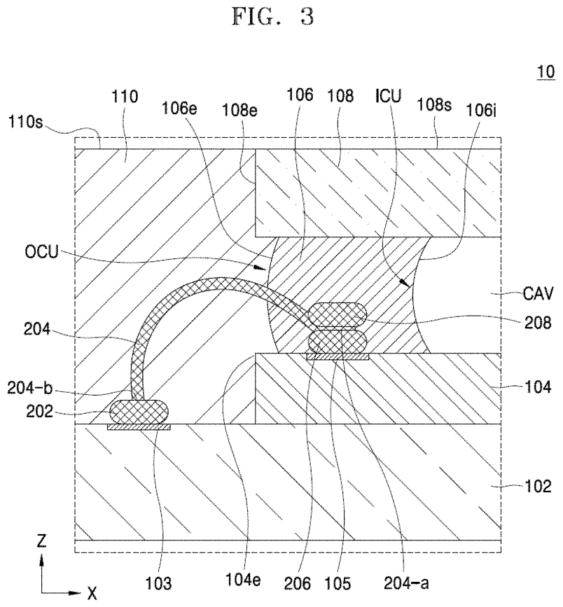

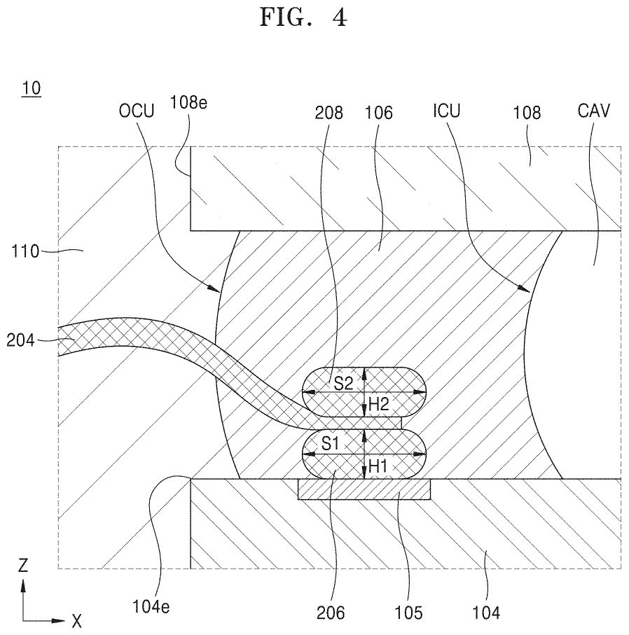

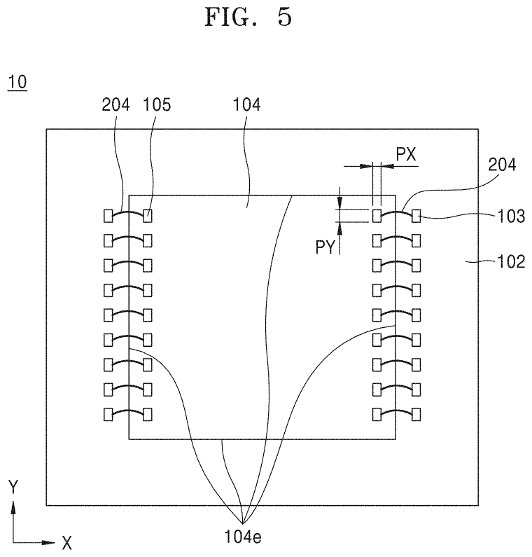

FIGS. 3 and 4 are partial cross-sectional views of the image sensor package 10 of FIG. 2 according to some example embodiments, and FIG. 5 is a plan view for explaining the connection relationship between the image sensor chip 104 and the circuit board 102 of the image sensor package 10 of FIGS. 1 and 2 according to some example embodiments.

In detail, FIG. 3 is a detailed diagram of a region “ENG” of FIG. 2, FIG. 4 is a diagram illustrating some components, and FIG. 5 is a diagram illustrating a connection of the image sensor chip 104 to the circuit board 102 by using the bonding wire 204.

The image sensor package 10 may include chip pads 105 disposed in the image sensor chip 104. As illustrated in FIG. 5, the chip pads 105 may be adjacent to both edges (e.g., opposite outer surfaces 104e) of the image sensor chip 104. The chip pads 105 may include pads that are apart from each other in the Y direction. The chip pad 105 may be referred to as a chip bonding pad. A size of the chip pad 105 in the X and Y directions may be PX and PY. In some example embodiments, PX and PY may be between about 60 μm and about 100 μm.

As illustrated in FIGS. 3 to 5, the stack bump structure (BOB of FIG. 2), which includes the first bump 206 and the second bump 208 disposed on the first bump 206, may be disposed on the chip pad 105. The stack bump structure (BOB of FIG. 2) may be adjacent to two or more edges (e.g., two or more outer surfaces 104e) of the image sensor chip 104.

In some example embodiments, the first bump 206 and the second bump 208 may each have a ball shape. In some example embodiments, on the cross-sectional view, the first bump 206 may have an oval shape. In some example embodiments, the first bump 206 may have a first width (or a first diameter) S1 and a first height H1. Compared to the first width (or the first diameter) S1, the first height H1 of the first bump 206 may be significantly small. In some example embodiments, the first width (or the first diameter) S1 may be between about 40 μm and about 50 μm. The first height H1 may be between about 5 μm and about 10 μm.

In some example embodiments, on the cross-sectional view, the second bump 208 may have an oval shape. In some example embodiments, the second bump 208 may have a second width (or a second diameter) S2 and a second height H2. Compared to the second width (or the second diameter) S2, the second height H2 of the second bump 208 may be significantly small. The second width (or the second diameter) S2 may be identical to the first width (or the first diameter) S1. The second height H2 may be identical to the first height H1. In some example embodiments, the second width (or second diameter S2) may be between about 40 μm and about 50 μm. The second height H2 may be between about 5 μm and about 10 μm.

In some example embodiments, the first width (or the first diameter) S1 of the first bump 206 may be equal to or greater than the second width (or the second diameter) S2 of the second bump 208, on a cross-sectional view (e.g., in a plane extending in the X and Z directions).

In some example embodiments, the first bump 206 and the second bump 208 may each have any one of an oval shape or a circular shape on a cross-sectional view (e.g., any one of an oval shape or a circular shape in a plane extending in the X and Z directions).

The image sensor package 10 may include substrate pads 103 disposed in the circuit board 102. The substrate pad 103 may be adjacent to both edges of the circuit board 102, as illustrated in FIG. 5. The substrate pad 103 may include pads that are apart from each other in the Y direction. The substrate pad 103 may be referred to as a substrate bonding pad. A size of the substrate pad 103 in the X and Y directions may be identical to a size of the chip pad 105.

As illustrated in FIGS. 3 and 4, the ball bump 202 may be disposed on the substrate pad 103. The stack bump structure (BOB of FIG. 2), which includes the first and second bumps 206 and 208 and is adjacent to two edges of the image sensor chip 104, may be electrically and physically connected to the ball bump 202 by using the bonding wire 204.

One end (e.g., a first end 204-a) of the bonding wire 204 may be between the first and second bumps 206 and 208, and the other end (e.g., the opposite, second end 204-b) of the bonding wire 204 may be on the circuit board 102 and may connect the image sensor chip 104 to the circuit board 102. Accordingly, the bonding wire 204 may electrically and physically connect the image sensor chip 104 and the circuit board 102 to each other. FIGS. 3 and 4 illustrate that the bonding wire 204 is a separate element from the first bump 206, but the bonding wire 204 and the first bump 206 may form an integral body. The bonding wire 204 may further connect the stack bump structure BOB and the circuit board 102 to each other.

The image sensor package 10 may include the dam element 106 covering the first bump 206, the second bump 208, and the bonding wire 204, on the image sensor chip 104. The dam element 106 may include an inner recess portion ICU, which is adjacent to the inner cavity CAV and recessed inwards, and an outer protruding portion OCU disposed outside the inner cavity CAV and protruding outwards. For example, as shown in at least FIG. 3, an outer surface 106e of the dam element 106 may have a convex shape in the Z-X and/or Z-Y plane and may have a central portion that protrudes outwards in the X direction and/or the Y direction relative to edge portions in contact with one of the optical element 108 or the image sensor chip 104, such that the outer surface 106e may at least partially define the outer protruding portion OCU of the dam element 106 which is distal from the inner cavity CAV in relation to the inner recess portion ICU and protrudes outwards from the inner cavity CAV. In addition, as shown in at least FIG. 3, an inner surface 106i of the dam element 106 may have a concave shape in the Z-X and/or Z-Y plane and may have a central portion that protrudes inwards in the X direction and/or the Y direction relative to edge portions in contact with one of the optical element 108 or the image sensor chip 104, such that the inner surface 106i may at least partially define the inner recess portion ICU of the dam element 106, where the inner recess portion ICU is adjacent to (e.g., at least partially defines) the inner cavity CAV and recessed inwards (e.g., towards a proximate outer surface 106e of the dam element 106 as shown in FIG. 3).

The image sensor package 10 may include the optical element 108 on the dam element 106. As described above, the optical element 108 may be supported by the dam element 106. The image sensor package 10 may include the molding element 110 contacting the dam element 106 on the circuit board 102 and covering (or sealing) the image sensor chip 104 and the bonding wire 204. As shown, the molding element 110 may surround the optical element 108 (e.g., in a plane extending in the X and Y directions).

As described above, in the image sensor package 10, the first bump 206 and the second bump 208 may support and protect the bonding wire 204 despite stress applied to the bonding wire 204 from the dam element 106 and the molding element 110. Accordingly, the image sensor package 10 may have the improved package reliability by restricting cutting of the bonding wire 204.

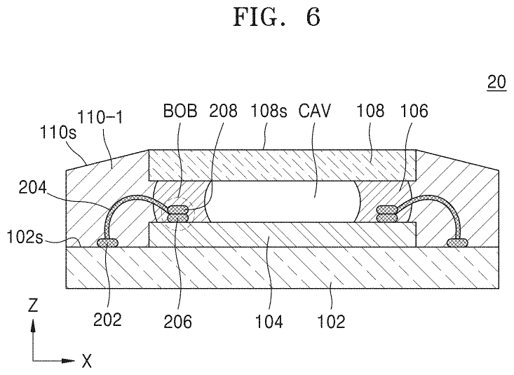

FIG. 6 is a cross-sectional view of an image sensor package according to some example embodiments.

In detail, an image sensor package 20 may be identical to the image sensor package 10 of FIGS. 1 to 5 except for a structure of a molding element 110-1. In FIG. 6, the same reference symbols as those in FIGS. 1 to 5 denote like elements. In FIG. 6, the same descriptions as those provided with reference to FIGS. 1 to 5 will be briefly provided or omitted.

The image sensor package 20 may include the circuit board 102, the image sensor chip 104, the stack bump structure BOB including the first and second bumps 206 and 208, the bonding wire 204, the dam element 106 including the inner cavity CAV, and the optical element 108.

The image sensor package 20 may include a molding element 110-1 contacting the dam element 106 on the circuit board 102 and surrounding the image sensor chip 104, the bonding wire 204, and the optical element 108. As shown in at least FIG. 6, an upper surface 110s of the molding element 110-1 may be at least partially at a lower level than the upper surface 108s of the optical element 108. When the upper surface 110s of the molding element 110-1 is at least partially at the lower level than the upper surface 108s of the optical element 108, the image sensor package 20 may have the improved package reliability by reducing the stress applied to the bonding wire 204 from the dam element 106 and the molding element 110-1.

As described herein, a “level” may refer to a distance from the upper surface 102s of the circuit board 102 in the Z direction which extends perpendicular to the upper surface 102s. Accordingly, when a first element (e.g., at least a portion of the upper surface 110s of the molding element 110-1) is at least partially at a lower level than another, second element (e.g., the upper surface 108s of the optical element 108), it will be understood that the first element is at least partially closer to the upper surface 102s of the circuit board 102 in the Z direction than the second element. In another example, elements at a same, or equal level will be understood to be a same, or equal distance from the upper surface 102s in the Z direction.

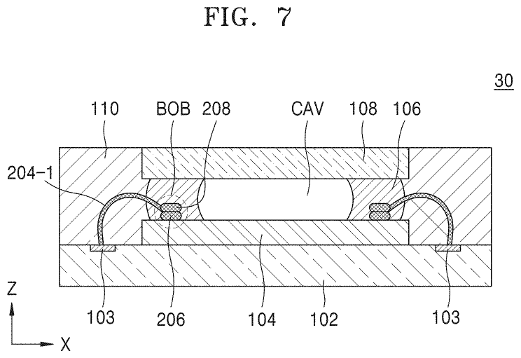

FIG. 7 is a cross-sectional view of an image sensor package according to some example embodiments.

In detail, an image sensor package 30 may be identical to the image sensor package of FIGS. 1 to 5 except for a bonding structure of the substrate pad 103 and the bonding wire 204. In FIG. 7, the same reference symbols as those in FIGS. 1 to 5 denote like elements. In FIG. 7, the same descriptions as those provided with reference to FIGS. 1 to 5 will be briefly provided or omitted.

The image sensor package 30 may include the circuit board 102, the image sensor chip 104, the stack bump structure BOB including the first and second bumps 206 and 208, a bonding wire 204-1, the dam element 106 including the inner cavity CAV, the optical element 108, and the molding element 110.

In the image sensor package 30, the substrate pad 103 on the circuit board 102 is stitch-bonded to the bonding wire 204-1. In other words, in the image sensor package 30, ball bumps may not be formed on the substrate pads 103 on the circuit board 102, and the bonding wire 204-1 may be electrically connected to the circuit board 102. As described, in the image sensor package 30, the substrate pad 103 on the circuit board 102 and the bonding wire 204-1 may be connected to each other in various manners.

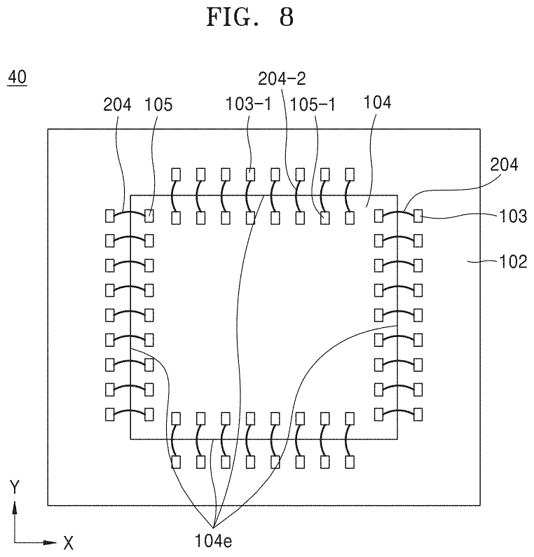

FIG. 8 is a plan view of an image sensor package according to some example embodiments.

In detail, an image sensor package 40 may be identical to the image sensor package 10 of FIGS. 1 to 5 except for arrangements of chip pads 105 and 105-1 and arrangements of substrate pads 103 and 103-1. In FIG. 8, the same reference symbols as those in FIGS. 1 to 5 denote like elements. In FIG. 8, the same descriptions as those provided with reference to FIGS. 1 to 5 will be briefly provided or omitted. The image sensor package 40 of FIG. 8 will be described in detail, compared to the image sensor package 10 of FIG. 5.

In the image sensor package 40, an image sensor chip 104 may be disposed on the circuit board 102. The image sensor chip 104 may include the chip pads 105 and 105-1. The chip pads 105 and 105-1 may be arranged adjacent to four edges or outer edges (e.g., four outer surfaces 104e) of the image sensor chip 104.

As illustrated in FIGS. 3 to 5, the stack bump structure (BOB of FIG. 2), which includes the first bump 206 and the second bump 208 disposed on the first bump 206, may be located on the chip pads 105 and 105-1. Accordingly, the stack bump structure (BOB of FIG. 2) may be adjacent to four edges, or outer edges (e.g., four outer surfaces 104e), of the image sensor chip 104.

The image sensor package 40 may include the substrate pads 103 and 103-1. The substrate pads 103 and 103-1 may be adjacent to four edges of the circuit board 102. The image sensor package 40 may include the first and second bumps 206 and 208, and the stack bump structure (BOB of FIG. 2), which is adjacent to four edges or outer edges (e.g., four outer surfaces 104e) of the image sensor chip 104, may be electrically and physically connected to the substrate pads 103 and 103-1 (and thus to the circuit board 102) by using bonding wires 204 and 204-2. As described, in the image sensor package 40, the substrate pads 103 and 103-1 on the circuit board 102 may be connected to the bonding wires 204 and 204-2 in various manners.

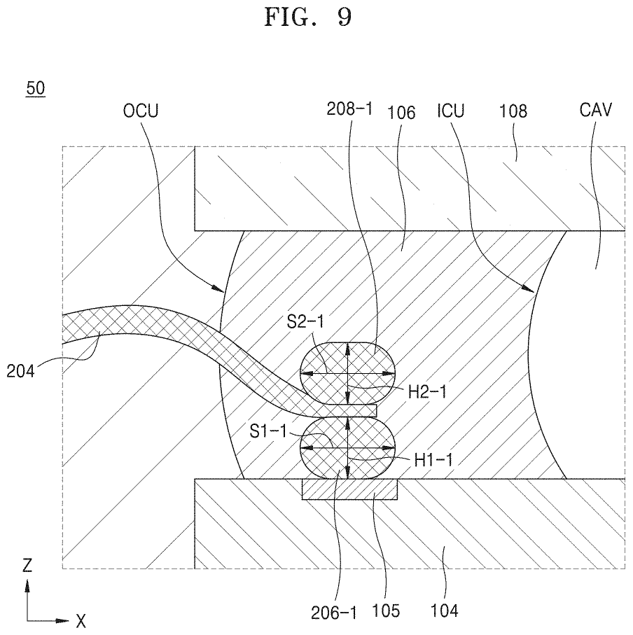

FIG. 9 is a cross-sectional view of an image sensor package according to some example embodiments.

In detail, an image sensor package 50 may be identical to the image sensor package 10 of FIGS. 1 to 5 except for structures of first and second bumps 206-1 and 208-1. In FIG. 9, the same reference symbols as those in FIGS. 1 to 5 denote like elements. In FIG. 9, the same descriptions as those provided with reference to FIGS. 1 to 5 will be briefly provided or omitted. The image sensor package 50 of FIG. 9 will be described in detail, compared to the image sensor package 10 of FIG. 4.

In the image sensor package 50, the stack bump structure (BOB of FIG. 2), which includes the first bump 206-1 and the second bump 208-1 on the first bump 206-1, may be located on the chip pad 105 of the image sensor chip 104. The bonding wire 204 may be between the first bump 206-1 and the second bump 208-1. The first bump 206-1 and the bonding wire 204 may form the same body. In some example embodiments, the first bump 206-1 and the second bump 208-1 may have ball shapes.

In some example embodiments, on a cross-sectional view, the first bump 206-1 may have an oval shape. In some example embodiments, the first bump 206-1 may have a third width (or a third diameter) S1-1 and a third height H1-1. The third height H1-1 of the first bump 206-1 may be greater than the first height H1 of the first bump 206 of FIG. 4. The third width (or the third diameter) S1-1 of the first bump 206-1 may be relatively less than the third height H1-1 thereof. In some example embodiments, the third width (or the third diameter) S1-1 may be between about 40 μm and about 50 μm. The third height H1-1 may be between about 5 μm and about 10 μm.

In some example embodiments, on the cross-sectional view, the second bump 208-1 may have an oval shape. In some example embodiments, the second bump 208-1 may have a fourth width (or a fourth diameter) S2-1 and a fourth height H2-1. The fourth width (or the fourth diameter) S2-1 may be identical to the third width (or the third diameter) S1-1.

The fourth height H2-1 of the second bump 208-1 may be greater than the second height H2 of the second bump 208 of FIG. 4. The fourth height H2-1 may be identical to the third height H1-1. The fourth height (or the fourth diameter) S2-1 of the second bump 208-1 may be relatively less than the fourth height H2-1 of the second bump 208-1. In some example embodiments, the fourth height (or the fourth diameter) S2-1 may be between about 40 μm and about 50 μm. The fourth height H2-1 may be between about 5 μm and about 10 μm.

The image sensor package 50 may include the dam element 106 covering the first bump 206-1, the second bump 208-1, and the bonding wire 204, on the image sensor chip 104. The dam element 106 may include the inner recess portion ICU and the outer protruding portion OCU. The image sensor package 50 may have the improved package reliability as structures of the first and second bumps 206-1 and 208-1 located in the dam element 106 vary.

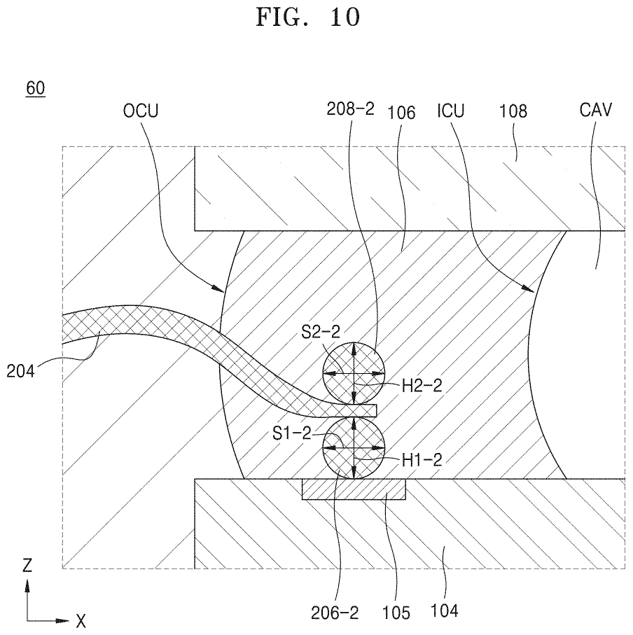

FIG. 10 is a cross-sectional view of an image sensor package according to some example embodiments.

In detail, an image sensor package 60 may be identical to the image sensor package 10 of FIGS. 1 to 5 except for structures of first and second bumps 206-2 and 208-2. In FIG. 10, the same reference symbols as those in FIGS. 1 to 5 denote like elements. In FIG. 10, the same descriptions as those provided with reference to FIGS. 1 to 5 will be briefly provided or omitted. The image sensor package 60 of FIG. 10 will be described in detail, compared to the image sensor package 10 of FIG. 4.

In the image sensor package 60, the stack bump structure (BOB of FIG. 2), which includes the first bump 206-2 and the second bump 208-2 on the first bump 206-2, may be located on the chip pad 105 of the image sensor chip 104. The bonding wire 204 may be between the first bump 206-2 and the second bump 208-2. The first bump 206-2 and the bonding wire 204 may form the same body. In some example embodiments, the first and second bumps 206-2 and 208-2 may have ball shapes.

In some example embodiments, on a cross-sectional view, the first bump 206-2 may have a circular shape. In some example embodiments, the first bump 206-2 may a fifth width (or a fifth diameter) S1-2 and a fifth height H1-2. The fifth width (or the fifth diameter) S1-2 may be between about 40 μm and about 50 μm. The first height H1-2 may be between about 5 μm and about 10 μm.

In some example embodiments, on the cross-sectional view, the second bump 208-2 may have a circular shape. In some example embodiments, the second bump 208-2 may have a sixth width (or a sixth diameter) S2-2 and a sixth height H2-2. The sixth width (or the sixth diameter) S2-2 may be identical to the fifth width (or the fifth diameter) S1-2. The sixth width (or the sixth diameter) S2-2 may be between about 40 μm and about 50 μm. The sixth height H2-2 may be identical to the fifth height H1-2. The sixth height H2-2 may be between about 5 μm and about 10 μm.

The image sensor package 50 may include the dam element 106 covering the first and second bumps 206-2 and 208-2 and the bonding wire 204, on the image sensor chip 104. The dam element 106 may include the inner recess portion ICU and the outer protruding portion OCU. The image sensor package 60 may have the improved package reliability as the structures of the first and second bumps 206-2 and 208-2 included in the dam element 106 vary.

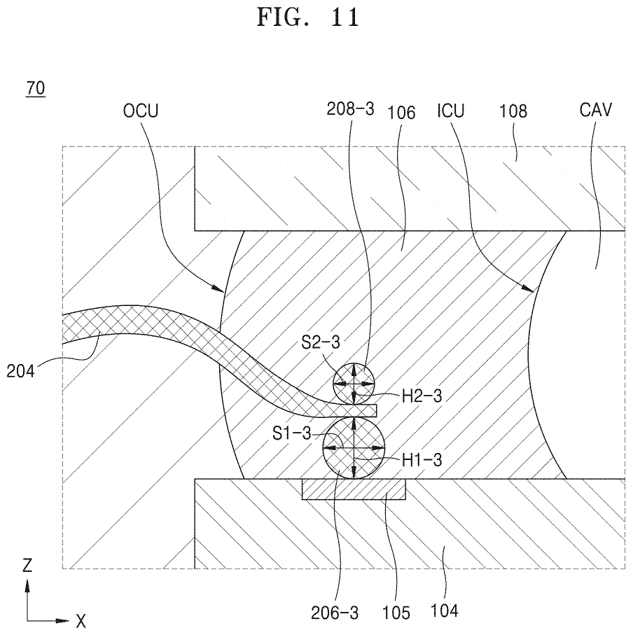

FIG. 11 is a cross-sectional view of an image sensor package according to some example embodiments.

In detail, an image sensor package 70 may be identical to the image sensor package 10 of FIGS. 1 to 5 except for structures of first and second bumps 206-3 and 208-3. In FIG. 11, the same reference symbols as those in FIGS. 1 to 5 denote like elements. In FIG. 11, the same descriptions as those provided with reference to FIGS. 1 to 5 will be briefly provided or omitted. The image sensor package 70 of FIG. 11 will be described in detail, compared to the image sensor package 10 of FIG. 4.

In the image sensor package 70, the stack bump structure (BOB of FIG. 2), which includes the first bump 206-3 and the second bump 208-3 on the first bump 206-3, may be located on the chip pad 105 of the image sensor chip 104. The bonding wire 204 may be between the first and second bumps 206-3 and 208-3. The first bump 206-3 and the bonding wire 204 may form the same body. In some example embodiments, the first bump 206-3 and the second bump 208-3 may have ball shapes.

In some example embodiments, on the cross-sectional view, the first bump 206-3 may have a circular structure. In some example embodiments, the first bump 206-3 may have a seventh width (or a seventh diameter) S1-3 and a seventh height H1-3. The seventh width (or the seventh diameter) S1-3 may be between about 40 μm and about 50 μm. The seventh height H1-3 may be between about 5 μm and about 10 μm.

In some example embodiments, on the cross-sectional view, the second bump 208-3 may have a circular structure. In some example embodiments, the second bump 208-3 may have an eighth width (or an eighth diameter) S2-3 and an eighth height H2-3. The eighth width (or the eighth diameter) S2-3 may be less than the seventh width (or the seventh diameter) S1-3. The eighth width (or the eighth diameter) S2-3 may be between about 40 μm and about 50 μm. The eighth height H2-3 may be less than the seventh height H1-3. The eighth height H2-3 may be between about 5 μm and about 10 μm.

The image sensor package 70 may include the dam element 106 covering the first and second bumps 206-3 and 208-3 and the bonding wire 204, on the image sensor chip 104. The dam element 106 may include the inner recess portion ICU and the outer protruding portion OCU. The image sensor package 70 may have the improved package reliability as the structures of the first and second bumps 206-3 and 208-3 included in the dam element 106 vary.

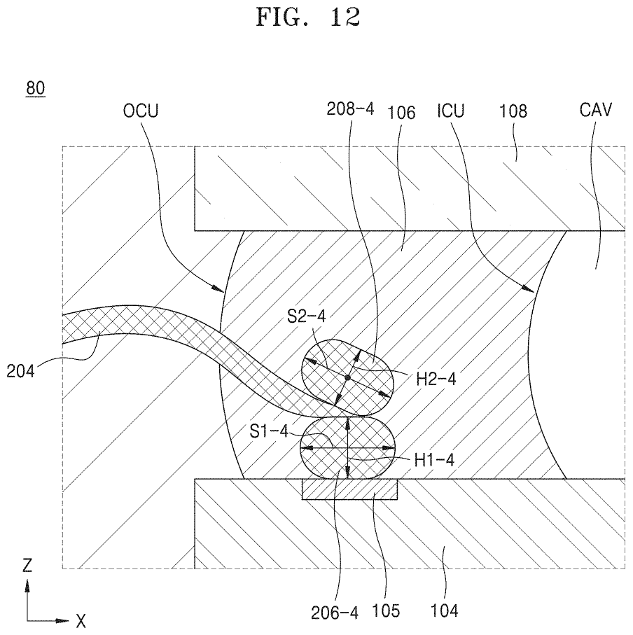

FIG. 12 is a cross-sectional view of an image sensor package according to some example embodiments.

In detail, an image sensor package 80 may be identical to the image sensor package 10 of FIGS. 1 to 5 except for structures of first and second bumps 206-4 and 208-4. In FIG. 12, the same reference symbols as those in FIGS. 1 to 5 denote like elements. In FIG. 12, the same descriptions as those provided with reference to FIGS. 1 to 5 will be briefly provided or omitted. The image sensor package 80 of FIG. 12 will be described in detail, compared to the image sensor package 10 of FIG. 4.

In the image sensor package 80, the stack bump structure (BOB of FIG. 2), which includes the first bump 206-4 and the second bump 208-4 on the first bump 206-4, may be located on the chip pad 105 of the image sensor chip 104. The bonding wire 204 may be between the first and second bumps 206-4 and 208-4. The first bump 206-4 and the bonding wire 204 may form the same body. In some example embodiments, the first bump 206-4 and the second bump 208-4 may have ball shapes.

In some example embodiments, on the cross-sectional view, the first bump 206-4 may have an oval structure. In some example embodiments, the first bump 206-4 may have a ninth width (or a ninth diameter) S1-4 and a ninth height H1-4. The ninth width (or the ninth diameter) S1-4 may be between about 40 μm and about 50 μm. The ninth height H1-4 may be between about 5 μm and about 10 μm.

In some example embodiments, on the cross-sectional view as shown for example in FIG. 12, the second bump 208-4 may have an oval structure. On the cross-sectional view, the second bump 208-4 may be tilted. For example, the greatest width of the second bump 208-4 (e.g., the tenth width S2-4) may extend in a plane that is angled (e.g., tilted) in relation to the plane through which the greatest width of the first bump 206-4 (e.g., the ninth width S1-4) extends such that said planes intersect each other (e.g., said planes may be angled in relation to each other so as to intersect in the X-Z plane as shown in FIG. 12). In other words, because the second bump 208-4 is tilted on the first bump 206-4, the second bump 208-4 adheres well to the bonding wire 204 to protect the same.

In some example embodiments, the second bump 208-4 may have a tenth width (or a tenth diameter) S2-4 and a tenth height H2-4. The tenth width (or the tenth diameter) S2-4 may be identical to the ninth width (or the ninth diameter) S1-4. The tenth width (or the tenth diameter) S2-4 may be between about 40 μm and about 50 μm. The tenth height H2-4 may be identical to the ninth height H1-4. The tenth height H2-4 may be between about 5 μm and about 10 μm.

The image sensor package 80 may include the dam element 106 covering the first and second bumps 206-4 and 208-4 and the bonding wire 204, on the image sensor chip 104. The dam element 106 may include the inner recess portion ICU and the outer protruding portion OCU. The image sensor package 80 may have the improved package reliability as the structures of the first and second bumps 206-4 and 208-4 included in the dam element 106 vary.

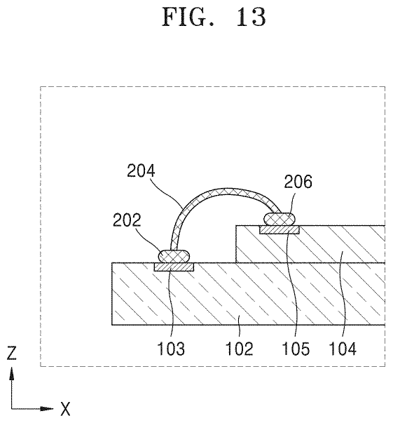

FIGS. 13, 14, 15, 16, and 17 are main cross-sectional views for explaining a manufacturing method of an image sensor package, according to some example embodiments.

FIG. 13 illustrates an operation of connecting the circuit board 102 and the image sensor chip 104 to each other by the bonding wire 204. The substrate pad 103 on the circuit board 102 is electrically and physically connected to the chip pad 105 on the image sensor chip 104 by the bonding wire 204.

The ball bump 202 is formed on an end of the bonding wire 204 by using a bonding device, and then, the ball bump 202 is bonded to the substrate pad 103 of the circuit board 102. After the bonding wire 204 extends and the first bump 206 is formed on the other end of the bonding wire 204 by using the bonding device, the first bump 206 is bonded to the chip pad 105 of the image sensor chip 104. The first bump 206 and the bonding wire 204 may form the same body.

As described above, when the circuit board 102 is connected to the image sensor chip 104 by the bonding wire 204, the reverse bonding method may be used. That is, the reverse bonding method may be a method of connecting the bonding wire 204 on the circuit board 102 in a direction towards the image sensor chip 104. When the reverse bonding method is used, the length of the bonding wire 204 may be reduced.

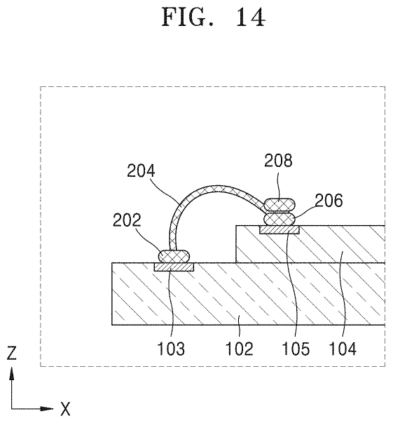

FIG. 14 illustrates an operation of forming the second bump 208 on the first bump 206 and/or the bonding wire 204. The stack bump structure (BOB of FIG. 2) is formed by forming the second bump 208 on the first bump 206. The second bump 208 is formed on the other end of the bonding wire 204, that is, the first bump 206, by using the bonding device. Accordingly, the stack bump structure (BOB of FIG. 2), which includes the first and second bumps 206 and 208, may be electrically and physically connected to the circuit board 102 by the bonding wire 204.

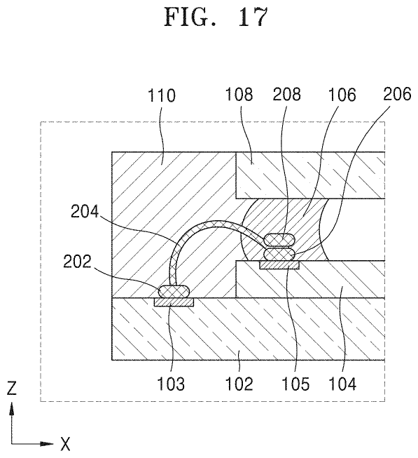

As the second bump 208 is formed on the other end of the bonding wire 204, that is, the first bump 206, the dam element (106 of FIG. 17) formed later may also prevent the bonding wire 204 from being cut despite the stress applied to the bonding wire 204 from the molding element (110 of FIG. 17).

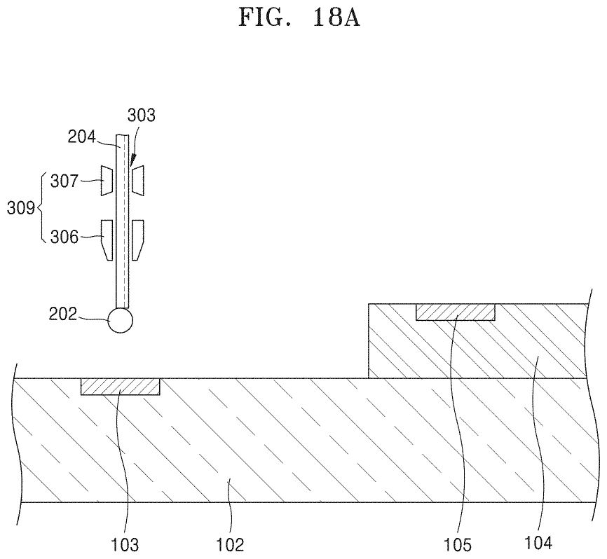

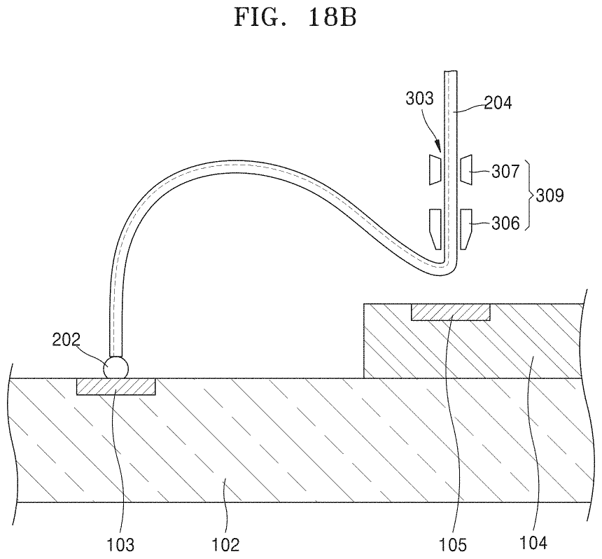

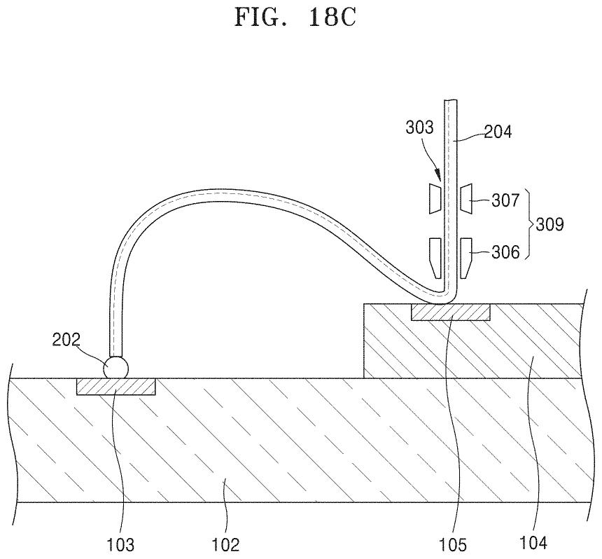

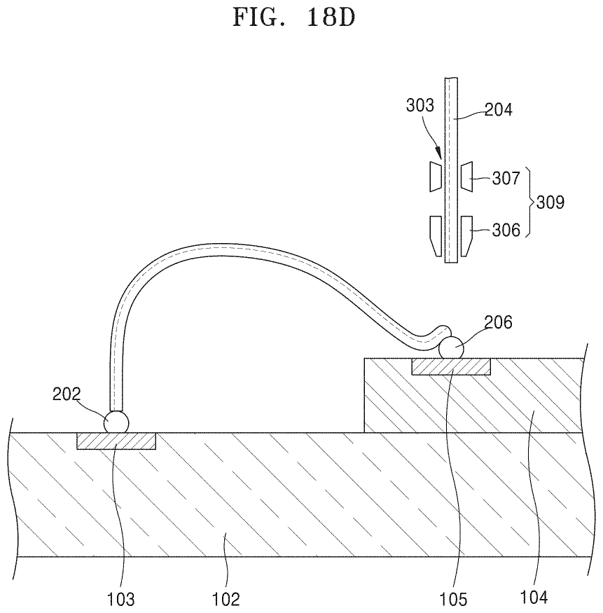

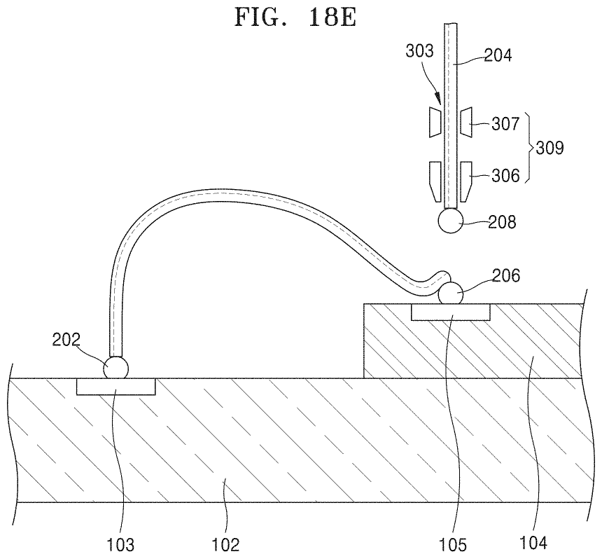

As described above with reference to FIGS. 13 and 14, the circuit board 102 may be connected to the image sensor chip 104 by the bonding wire 204 by using the bonding device. A detailed method of connecting the circuit board 102 to the image sensor chip 104 by using the bonding device described with reference to FIGS. 13 and 14 will be described in more detail with reference to FIGS. 18A to 18E.

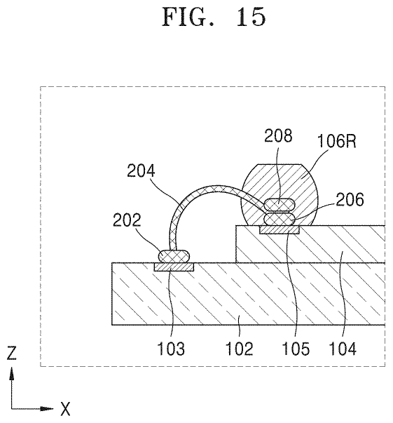

FIG. 15 illustrates an operation of forming, on the image sensor chip 104, a glue element 106R covering the first and second bumps 206 and 208.

The glue element 106R is formed on the image sensor chip 104, the first bump 206, the bonding wire 204 on an upper portion of the first bump 206 and the image sensor chip 104, and the second bump 208. Specifically, the glue element 106R may be formed on a portion of the bonding wire 204 on the image sensor chip 104.

Accordingly, stress may be applied to the bonding wire 204 because of the glue element 106R. The glue element 106R may be hardened later and become the dam element (106 of FIG. 17). The glue element 106R may include thermosetting resin such as epoxy resin, thermoplastic resin such as polyimide, and resin formed by including a reinforcement material such as an inorganic filler in the thermosetting resin and the thermoplastic resin.

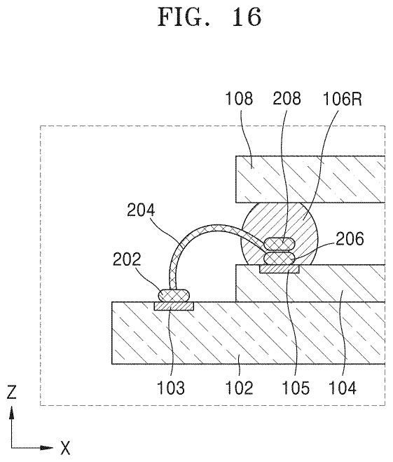

FIG. 16 illustrates an operation of mounting the optical element 108 on the glue element 106R. As described above, the optical element 108 may include at least one material selected from sapphire, glass, reinforced glass, plastic, a polycarbonate (PC)-based material, and a polyamide (PI)-based material. The optical element 108 may be a lens of which optical features such as a refractive index, magnetic permeability, and the like are designed within a desired range.

FIG. 17 illustrates an operation of forming the molding element 110. The molding element 110 covering a periphery (e.g., outer surfaces 104e) of the image sensor chip 104, the bonding wire 204, and the optical element 108 is formed on the circuit board 102. In other words, the molding element 110 sealing the image sensor chip 104, the bonding wire 204, and the optical element 108 is formed on the circuit board 102.

In some example embodiments, the upper surface of the molding element 110 may be on the same plane as the upper surface of the optical element 108 as illustrated in FIG. 17. In some example embodiments, the upper surface 110s of the molding element 110 may be at least partially at a lower level than the upper surface 108s of the optical element 108, as illustrated in FIG. 6. Because the molding element 110 covers (seals) the bonding wire 204 on the circuit board 102, the molding element 110 may apply stress to the bonding wire 204.

The molding element 110 may include a material different from that of the glue element 106R. When the molding element 110 is formed, the glue element 106R may prevent the penetration of the molding element 110 into the image sensor chip 104. As described above, the molding element 110 may include thermosetting resin such as epoxy resin, thermoplastic resin such as polyimide, and resin formed by including a reinforcement material such as an inorganic filler in the thermosetting resin and the thermoplastic resin. In some example embodiments, the molding element 110 may be an epoxy molding compound or an adhesive film.

When or after the molding element 110 is formed, the glue element 106R may be hardened and become the dam element 106. When the glue element 106R is hardened and becomes the dam element 106, the dam element 106 may apply the stress to the bonding wire 204. When the glue element 106R is hardened and becomes the dam element 106, the dam element 106 may include the inner recess portion (ICU of FIGS. 3 and 4) and the outer protruding portion (OCU of FIGS. 3 and 4).

Because the image sensor package manufactured as described above includes the stack bump structure (BOB of FIG. 2) including the first and second bumps 206 and 208, the bonding wire 204, which connects the circuit board 102 to the image sensor chip 104, may be less likely cut because of the stress applied to the dam element 106 and the molding element 110, and thus, the package reliability may be improved.

FIGS. 18A, 18B, 18C, 18D, and 18E are main cross-sectional views for explaining a wire bonding method of FIGS. 13 and 14 using a bonding device.

FIG. 18A illustrates an operation of forming the ball bump 202 on the bonding wire 204 by locating a bonding device 309 on the substrate pad 103 of the circuit board 102. The substrate pad 103 may be formed on the circuit board 102. The image sensor chip 104 may be attached to the circuit board 102. For convenience, FIG. 18A illustrates that a height (or a thickness) of the image sensor chip 104 is great.

The bonding device 309 is located on the substrate pad 103 of the circuit board 102. The bonding device 309 includes a guide element 307 and a capillary element 306. A through hole 303 is formed in the bonding device 309, that is, the guide element 307 and the capillary element 306. After the bonding wire 204 passes through the through hole 303, the ball bump 202 is formed on one end of the bonding wire 204. The ball bump 202 may be formed by generating an electrical discharge, for example, a spark discharge, on one end of the bonding wire 204. The generation of the electrical discharge on the end of the bonding wire 204 may be performed by using a spark electrode included inside or outside the bonding device 309.

FIG. 18B illustrates an operation of bonding the ball bump 202 on the substrate pad 103 of the circuit board 102 and moving the bonding device 309 including the bonding wire 204 to an upper portion of the chip pad 105 of the image sensor chip 104.

The ball bump 202 is bonded on the substrate pad 103 of the circuit board 102. By descending the bonding device 309, the ball bump 202 formed on the end of the bonding wire 204 is bonded on the substrate pad 103. The ball bump 202 formed on the end of the bonding wire 204 is bonded on the substrate pad 103 according to a compression method, for example, a thermo-compression method. A method of forming and then bonding the ball bump 202 may be referred to as a ball bonding method, such that when the circuit board 102 and the bonding wire 204 are bonded to each other in a ball bonding manner, the image sensor package 10 includes a ball bump 202 between (e.g., directly between, connecting, etc.) the bonding wire 204 and a substrate pad 103 of the circuit board 102.

According to the necessity, a ball bump may not be formed on an end of the bonding wire 204, and the bonding wire 204 may be directly bonded on the substrate pad 103. A method whereby the ball bump is not formed on an end of the bonding wire 204 may be referred to as a stitch bonding method, such that when the circuit board 102 and the bonding wire 204 are bonded to each other in a stitch bonding manner, the image sensor package 10 includes the bonding wire 204 directly bonded on the substrate pad 103 of the circuit board 102 without any ball bump between the bonding wire 204 and the substrate pad 103 (e.g., no ball bump is present between the bonding wire 204 and the substrate pad 103 to which the bonding wire 204 is bonded). The bonding device 309 including the bonding wire 204 may be moved to the upper portion of the chip pad 105 of the image sensor chip 104.

FIGS. 18C and 18D illustrate operations of attaching the bonding wire 204 to the chip pad 105 of the image sensor chip 104 and forming the first bump 206. As illustrated in FIG. 18C, the bonding wire 204 is located on the chip pad 105 of the image sensor chip 104 by moving the bonding device 309.

The first bump 206 is formed on the end of the bonding wire 204 located on the chip pad 105 of the image sensor chip 104. The first bump 206 may have a ball shape. The first bump 206 may be formed by generating an electrical discharge, for example, a spark discharge, on a portion of the bonding wire 204 located on the chip pad 105. The generation of the electrical discharge on a portion of the bonding wire 204 may be performed by using the spark electrode included inside or outside the bonding device 309.

The first bump 206 and the bonding wire 204 may form the same body. The bonding wire 204 may be coupled to the first bump 206. The first bump 206, which is formed on the portion of the bonding wire 204, is bonded to the chip pad 105 by using the bonding device 309. The first bump 206, which is formed on the portion of the bonding wire 204, is bonded to the chip pad 105 according to the compression method, for example, the thermo-compression method.

The method of forming and then bonding the first bump 206 having the ball shape may be referred to as the ball bonding method. The bonding wire 204 bonded to the chip pad 105 is completely separated from the bonding wire 204 included in the bonding device 309 by moving the bonding device 309 to the upper portion of the chip pad 105.

FIG. 18E illustrates an operation of forming the second bump 208 on the bonding wire 204 included in the bonding device 309. As illustrated in FIG. 18E, the second bump 208 is formed on an end of the bonding wire 204 included in the bonding device 309. The second bump 208 may have a ball shape.

The second bump 208 may be formed by generating an electrical discharge, for example, a spark discharge, on an end of the bonding wire 204 included in the bonding device 309. The generation of the electrical discharge on an end of the bonding wire 204 included in the bonding device 309 may be performed by using the spark electrode included inside or outside the bonding device 309.

The second bump 208, which is formed on the end of the bonding wire 204 included in the bonding device 309, may descend. When the operation is performed as stated, the second bump 208 may be mounted on the first bump 206 as illustrated in FIG. 14. In other words, the second bump 208 may be mounted on the first bump 206 including the bonding wire 204.

The first bump 206 including the bonding wire 204 may be bonded to the second bump 208 by using the bonding device 309. The first bump 206 may be bonded to the second bump 208 by using the compression method, for example, the thermo-compression method. The method of forming and then bonding the second bump 208 having the ball shape to the first bump 206 may be referred to as the ball bonding method.

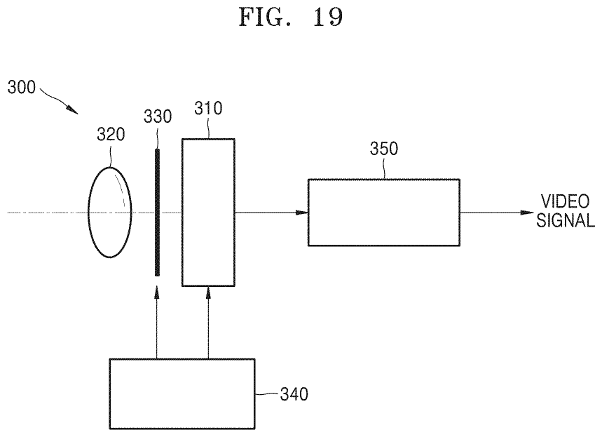

FIG. 19 is a structure diagram of a camera using an image sensor package, according to some example embodiments.

In detail, a camera 300 includes an image sensor package 310, an optical system 320 guiding incident light to a light reception sensor (or an image sensing area) of the image sensor package 310, a shutter device 330, a driving circuit 340 driving the image sensor package 310, and a signal processing circuit 350 processing an output signal of the image sensor package 310.

The image sensor package 310 may be formed by applying any one of the image sensor packages 10 to 80 according to the some example embodiments. The optical system 320 including an optical lens forms image light, that is, incident light, from a subject on an imaging surface of the image sensor package 310. To this end, signal charges are accumulated in the image sensor package 310 for a certain period of time.

The optical system 320 may include optical lenses. The shutter device 330 controls a light irradiation period and a light shield period of the image sensor package 310. The driving circuit 340 provides a driving signal to the image sensor package 310 and the shutter device 330 and controls an operation, in which a signal is output from the image sensor package 310 to the signal processing circuit 350, and a shutter operation of the shutter device 330, according to the provided driving signal or a timing signal.

The driving circuit 340 performs the operation, in which a signal is output from the image sensor package 310 to the signal processing circuit 350, according to the provided driving signal or timing signal. The signal processing circuit 350 performs various signal processing operations on signals transmitted from the image sensor package 310. Video signals, on which signal processing is performed, is recorded on a recording medium such as a memory or output to a monitor.

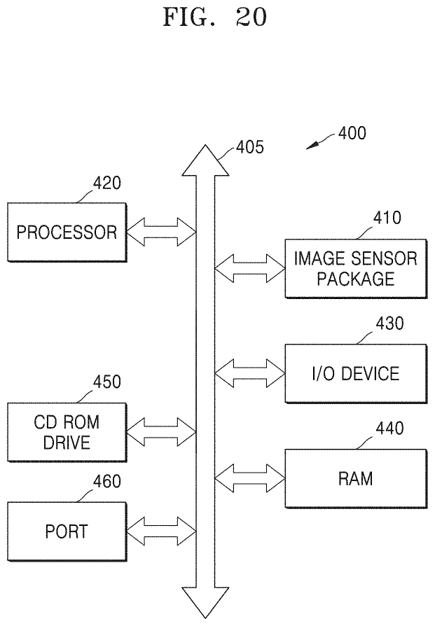

FIG. 20 is a block structure diagram of an imaging system including an image sensor package, according to some example embodiments.

In detail, an imaging system 400 processes an output image of the image sensor package 410. The imaging system 400 may be all types of electronic systems, for example, a computer system, a camera system, a scanner, an imaging stabilizing system, and the like, on which the image sensor package 410 is mounted. The image sensor package 410 may be formed by applying any one of the image sensor packages 10 to 80 according to the some example embodiments.

The imaging system 400, for example, a computer system, which is processor-based, may include a processor 420 such as a microprocessor or a central processing unit (CPU) capable of communicating with an input/output (I/O) device 430 through a bus 405. A CD ROM drive 450, a port 460, and RAM 440 may be connected to the processor 420 through the bus 405 for data exchange, and thus, an output image regarding data of the image sensor package 410 may be reproduced.

The port 460 may be a port for coupling a video card, a sound card, a memory card, a USB device, and the like or a port through which data is exchanged with another system. The image sensor package 410 may be integrated together with a CPU, a digital signal processor (DSP), or processors such as a microprocessor, or may be integrated together with a memory. In some cases, the image sensor package 410 may be integrated independently from a processor. The imaging system 400 may be a system block diagram of a camera phone, a digital camera, or the like.

The camera 300 shown in FIG. 19, the imaging system 400 shown in FIG. 20, and/or any portions thereof (e.g., image sensor package 310, optical system 320, shutter device 330, driving circuit 340, signal processing circuit 350, image sensor package 410, processor 420, input/output (I/O) device 430, CD ROM drive 450, port 460, RAM 440, or the like), may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device, for example a solid state drive (SSD), storing a program of instructions, and a processor (e.g., CPU) configured to execute the program of instructions to implement the functionality and/or methods performed by the camera 300 shown in FIG. 19, the imaging system 400 shown in FIG. 20, and/or any portions thereof.

While the inventive concepts have been particularly shown and described with reference to some example embodiments thereof, it will be understood that various changes in form and details may be made therein without departing from the spirit and scope of the following claims.

What is claimed is:

1. An image sensor package, comprising:
a circuit board;
an image sensor chip on the circuit board;
a stack bump structure on the image sensor chip;
a bonding wire connecting the circuit board to the stack bump structure;
a dam element on the image sensor chip, the dam element covering both the stack bump structure and the bonding wire; and
a molding element contacting the dam element on the circuit board, the molding element covering both the image sensor chip and the bonding wire.

2. The image sensor package of claim 1, wherein
the stack bump structure includes
a first bump, and
a second bump on the first bump, and
the first bump is on the image sensor chip.

3. The image sensor package of claim 2, wherein the first bump and the bonding wire are separate portions of a single, continuous piece of material.

4. The image sensor package of claim 1, wherein the dam element includes a material different from a material of the molding element.

5. The image sensor package of claim 1, wherein a maximum height from an upper surface of the circuit board to the bonding wire in a vertical direction is less than a sum of a thickness of the image sensor chip in the vertical direction and a thickness of the dam element in the vertical direction, the vertical direction being perpendicular to the upper surface of the circuit board.

6. The image sensor package of claim 1, wherein
the dam element is adjacent to opposite outer surfaces of the image sensor chip, and
an optical element is further on the dam element that is adjacent to the opposite outer surfaces of the image sensor chip.

7. The image sensor package of claim 1, wherein
the circuit board and the bonding wire are bonded to each other in a ball bonding manner such that the image sensor package includes a ball bump between the bonding wire and a substrate pad of the circuit board, or
the circuit board and the bonding wire are bonded to each other in a stitch bonding manner such that the bonding wire is directly bonded to the substrate pad of the circuit board without any ball bump between the bonding wire and the substrate pad.

8. The image sensor package of claim 2, wherein the first bump and the second bump have any one of an oval shape or a circular shape on a cross-sectional view.

9. The image sensor package of claim 2, wherein a width of the first bump is equal to or greater than a width or a diameter of the second bump, on a cross-sectional view.

10. The image sensor package of claim 2, wherein the second bump is tilted in relation to the first bump on a cross-sectional view, such that a greatest width of the second bump extends in a plane that is angled in relation to a separate plane through which a greatest width of the first bump extends, such that the plane and the separate plane intersect each other.

11. An image sensor package, comprising:
a circuit board;
an image sensor chip on the circuit board;
a stack bump structure adjacent to outer surfaces of the image sensor chip, the stack bump structure including a first bump and a second bump on the first bump;
a bonding wire having
a first end that is located between the first bump and the second bump, and an opposite second end that is on the circuit board and connects the image sensor chip to the circuit board;
a dam element covering both the stack bump structure and the bonding wire, the dam element located along a periphery of the image sensor chip, the dam element including at least one inner surface at least partially defining an inner cavity within the dam element; and
a molding element located along a periphery of the dam element on the circuit board and sealing both the image sensor chip and the bonding wire.

12. The image sensor package of claim 11, further comprising an optical element on the dam element.

13. The image sensor package of claim 12, wherein the molding element surrounds the optical element.

14. The image sensor package of claim 11, wherein
the stack bump structure is adjacent to opposite outer surfaces of the image sensor chip, and
the bonding wire connects the stack bump structure and the circuit board to each other.

15. The image sensor package of claim 11, wherein
the stack bump structure is adjacent to four outer surfaces of the image sensor chip, and
the bonding wire connects the circuit board to the stack bump structure.

16. The image sensor package of claim 11, wherein the dam element includes a material different from a material of the molding element.

17. An image sensor package, comprising:
a circuit board;
an image sensor chip on the circuit board;
a stack bump structure adjacent to opposite outer surfaces of the image sensor chip, the stack bump structure including a first bump and a second bump on the first bump;
a bonding wire having
a first end that is located between the first bump and the second bump, and
an opposite second end that is located on the circuit board and connects the image sensor chip to the circuit board;
a dam element covering both the stack bump structure and the bonding wire, the dam element adjacent to the opposite outer surfaces of the image sensor chip, the dam element including at least one inner surface at least partially defining an inner cavity within the dam element, the inner cavity exposing a central portion of the image sensor chip;
an optical element on the dam element; and
a molding element sealing both the image sensor chip and the bonding wire, the molding element located on opposite outer surfaces of the optical element, wherein the molding element includes a material different from a material of the dam element.

18. The image sensor package of claim 17, wherein the dam element includes an inner recess portion, which is adjacent to the inner cavity and recessed inwards towards an outer surface of the dam element, and an outer protruding portion distal from the inner cavity in relation to the inner recess portion and protruding outwards from the inner cavity.

19. The image sensor package of claim 17, wherein an upper surface of the molding element is coplanar with an upper surface of the optical element.

20. The image sensor package of claim 17, wherein an upper surface of the molding element is at least partially at a lower level than an upper surface of the optical element.
